(19) United States
(12) Patent Application Publication
(10) Pub. No.: US 2025/0301850 A1
(43) Pub. Date: Sep. 25, 2025

(54) OPTICAL INTERCONNECTS USING 3D STACKED OPTOELECTRONIC INTERFACES

(71) Applicants: Robert Kalman, Sunnyvale, CA (US); Sunghwan Min, Sunnyvale, CA (US); Bardia Pezeshki, Sunnyvale, CA (US); Ivan Huang, Sunnyvale, CA (US); Emad Afifi, Sunnyvale, CA (US); Alexander Tselikov, Sunnyvale, CA (US)

(72) Inventors: Robert Kalman, Sunnyvale, CA (US); Sunghwan Min, Sunnyvale, CA (US); Bardia Pezeshki, Sunnyvale, CA (US); Ivan Huang, Sunnyvale, CA (US); Emad Afifi, Sunnyvale, CA (US); Alexander Tselikov, Sunnyvale, CA (US)

(21) Appl. No.: 19/088,679

(22) Filed: Mar. 24, 2025

Related U.S. Application Data
(60) Provisional application No. 63/569,358, filed on Mar. 25, 2024.

(51) Int. Cl. H10H 29/85; H01L 25/16

(52) U.S. Cl. CPC H10H 29/857; H01L 25/167; H10H 29/8506

(57) ABSTRACT

An optical interconnect may include an optoelectronic IC mounted to a substrate. The optoelectronic IC may have optoelectronic devices, for example microLEDs and/or photodetectors, mounted to a surface of the optoelectronic IC away from the substrate. The optoelectronic IC may have circuitry for driving the microLEDs and/or processing electrical signals from the photodetectors. The optoelectronic IC may be interfaced to a D2D interface chip. The D2D interface chip may be mounted to the optoelectronic IC.

### CROSS-REFERENCE TO RELATED APPLICATIONS

This application claims the benefit of U.S. Provisional Patent Application No. 63/569,358, filed on Mar. 25, 2024, the disclosure of which is incorporated by reference herein.

### BACKGROUND OF THE INVENTION

The need for high-performance computing and networking is ubiquitous and ever-increasing. Prominent applications include data center servers, high-performance computing clusters, artificial neural networks, and network switches.

Processing capabilities of integrated circuits (ICs) have been advancing faster than their IO for decades. This has resulted in problems such as the “memory wall,” where the performance of processing systems is limited to far less than optimum due to memory IO limitations.

A single IC can only contain so much functionality based on transistor count and power constraints. Additionally, different functions (e.g. logic, DRAM, I/O) require different process sequences, and thus not all the desired functions can be combined on a single integrated circuit.

In fact, there are significant benefits to “de-integrating” SoCs into smaller “chiplets”, including: the process for each chiplet can be optimized to its function, e.g. logic, DRAM, high-speed I/O, etc.; chiplets are well-suited to reuse in multiple designs; chiplets are less expensive to design; chiplets have higher yield because they are smaller with fewer devices.

However, a major drawback to chiplets compared to SoCs is that chiplets require a higher density of inter-chip connections. Compared to the on-chip connections between functional blocks in SoCs, chip-to-chip connections are typically much less dense and require far more power (normalized as energy per bit).

State-of-the-art chip-to-chip interconnects utilize interposers and bridges, where the chips are flip-chip bonded to a substrate that contains the chip-to-chip electrical traces. While such interconnects provide far higher density and far lower power than interconnects of packaged chips via a printed circuit board (PCB), they still fall very far short of what is desired: chip-to-chip interconnects that approach the density and power dissipation of intra-chip interconnects.

The power and maximum reach of electrical interconnects are fundamentally limited by capacitance and conductor resistance. Interconnect density is limited by conductor width and layer count. The capacitance C of short electrical interconnects is proportional to interconnect length and approximately independent of conductor width w (assuming dielectric thickness scales approximately proportionately). The resistance R of electrical connections, and thus the maximum length (limited by RC) is inversely proportional to the conductor cross-sectional area, which scales as w². The density of electrical connections is inversely proportional to w. Thus, there are trade-offs in interconnect density, length, and power, and these trade-offs are fundamental, being based on dielectric permittivity and conductor (e.g. copper) resistance.

Thus electrical interconnects have fundamental limitations that constrain system performance and limit what is achievable with so-called “more than Moore” 2.5D and 3D advanced packaging.

### BRIEF SUMMARY OF THE INVENTION

The drive power and density of optical interconnects are independent of the length of the connection. With regard to density, multi-layer planar optical interconnects can achieve densities that are on the same order of the density of electrical interconnects. However, “3D” optical interconnects that are normal to the chip surface, possibly can achieve extraordinary densities that are far beyond what is possible with planar interconnects; densities of >2500 interconnects per mm² at 4 Gbps data rates are readily achievable, providing a throughput density of >1 Pbps/cm².

Some embodiments provide optical interconnects based on an optoelectronic IC chip bonded to a base IC chip in a “3D” stack. In some embodiments the optoelectronic IC has an active layer including optical drive circuitry and optical receive circuitry. Optical emitters, for example microLEDs, are bonded to the optoelectronic IC, and driven by the optical drive circuitry. Optical detectors, for example photodetectors, are also bonded to the optoelectronic IC, or formed in the optoelectronic IC, and coupled to the optical receive circuitry. In some embodiments the optical detectors are in a layer on top of or over the optoelectronic IC, and the optical emitters are bonded to the layer containing the optical detectors. The optical emitters and the optical detectors may both be arranged in an array or arrays, either separately or combined. The arrays may be on a first surface area of the optoelectronic IC, with the base IC chip and the optoelectronic IC chip bonded together on a second surface area of the optoelectronic IC, with the first area and the second area being different areas. In some embodiments the optoelectronic IC includes through silicon vias (TSVs) connecting the opposing surfaces of the optoelectronic IC, with the base IC chip coupled to the TSVs so as to allow the base IC chip to receive and provide signals to another chip, for example a processor. The base IC chip and the optical drive circuitry and optical receive circuitry are also electrically coupled, through metal layers and/or circuitry of the active layer of the optoelectronic IC. In some embodiments the active layer of the optoelectronic IC includes buffers to assist in passing signals between the optoelectronic IC and the base IC.

Some embodiments in accordance with aspects of the invention provide a device for an optical interconnect, comprising: a substrate; and an optoelectronic IC having a first surface mounted to the substrate, with optoelectronic devices on a second surface of the substrate, the optoelectronic devices including microLEDs, the optoelectronic IC including die-to-die (D2D) interface circuitry for receiving information and LED driver circuitry for driving the microLEDs based on the information. Some embodiments further comprise a D2D interface chip, the D2D interface chip including D2D interface circuitry coupled to the D2D interface circuitry of the optoelectronic IC.

In some embodiments the D2D interface chip is mounted to the second surface of the optoelectronic IC. In some embodiments a D2D interface between the optoelectronic IC and the D2D interface is a vertical D2D interface. Some embodiments further comprise a processor mounted to the substrate, the processor coupled to the optoelectronic IC so as to provide the information to the optoelectronic IC for driving the microLEDs. In some embodiments the D2D interface chip includes additional D2D interface circuitry, and further comprising a processor mounted to the substrate, the processor including D2D interface circuitry coupled to the additional D2D interface circuitry of the D2D interface chip. In some embodiments the optoelectronic IC includes TSVs providing at least part of an electrical pathway between the substrate and the second surface of the optoelectronic IC. Some embodiments further comprise a processor mounted to the substrate, the processor including D2D interface circuitry coupled to the additional D2D interface circuitry of the D2D interface chip by electrical pathways in or on the substrate and the TSVs. In some embodiments the D2D interface circuitry of the processor is coupled to the additional D2D interface of the D2D interface chip by a horizontal D2D interface.

In some embodiments the optoelectronic devices further include photodetectors and receive circuitry coupled to the photodetectors. In some embodiments the receive circuitry is coupled to the D2D interface circuitry of the optoelectronic IC. Some embodiments further comprise a D2D interface chip, the D2D interface chip including D2D interface circuitry coupled to the D2D interface circuitry of the optoelectronic IC. In some embodiments the D2D interface chip is mounted to the second surface of the optoelectronic IC. In some embodiments the D2D interface chip includes additional D2D interface circuitry, and such embodiments may further comprise a processor mounted to the substrate, the processor including D2D interface circuitry coupled to the additional D2D interface circuitry of the D2D interface chip. In some embodiments the optoelectronic IC includes TSVs providing at least part of an electrical pathway between the substrate and the second surface of the optoelectronic IC, and such embodiments may further comprise a processor mounted to the substrate, the processor including D2D interface circuitry coupled to the additional D2D interface circuitry of the D2D interface chip by electrical pathways in or on the substrate and the TSVs.

These and other aspects are more fully comprehended upon review of this disclosure.

### BRIEF DESCRIPTION OF THE FIGURES

FIGS. 1a-b illustrate a side view and a top view of a multi-chip package, respectively, in accordance with aspects of the invention.

FIG. 2 shows a cross-section of an embodiment of a fiber bundle.

FIGS. 3a-d are block diagrams of embodiments of one end of an optical interconnect between ICs, in accordance with aspects of the invention.

FIGS. 4a-e are cross-sectional views of embodiments of optoelectronic subassemblies, in accordance with aspects of the invention.

FIGS. 5a-c show top and side views illustrating relative areas of embodiments of base ICs and optoelectronic ICs bonded together, in accordance with aspects of the invention.

FIGS. 6a-h are front-side cross-sectional views showing relative arrangements of base ICs, optoelectronic ICs, and substrates, in accordance with aspects of the invention.

FIGS. 7a-b are front-side cross-sectional views showing relative arrangements of base ICs, optoelectronic substrates, and molded wafers, in accordance with aspects of the invention.

FIG. 8 shows an idealized perspective view of an implementation in accordance with aspects of the invention.

FIG. 9 shows a semi-block diagram cross-section of the implementation of FIG. 8.

### DETAILED DESCRIPTION

The inventions discussed herein relate to implementations of vertical optical input/output (IO) interfaces within, or in some embodiments between, multi-chip packages (MCPs). An MCP generally comprises multiple integrated circuits (ICs or “chips”) that are electrically interconnected to each other and to an external printed circuit board (PCB) via a package substrate.

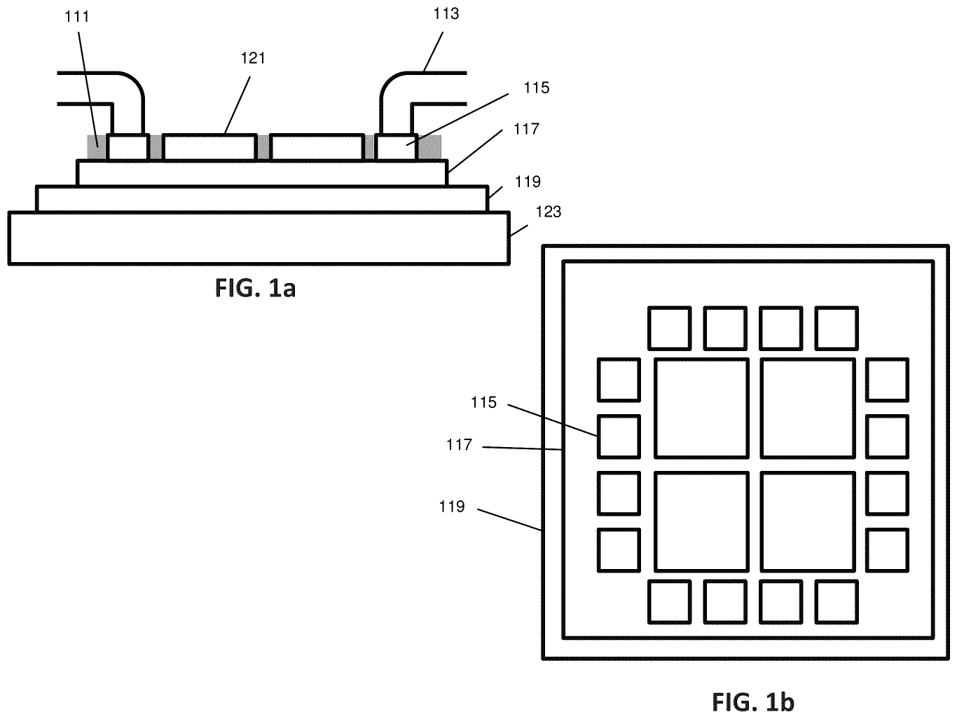

FIGS. 1a and 1b illustrate a side view and a top view, respectively, of a multi-chip package. The MCP may comprise a diversity of ICs, such as complex system-on-chips (SoCs) 121 that comprise primarily processing or digital switching functionality, for example as shown in FIGS. 1a,b. Examples of processing SoCs are central processing units (CPUs), graphical processing units (GPUs), data processing units (DPUs), tensor processing units (TPUs), and network processing units (NPUs). An MCP may also comprise ICs 115 that provide IO functionality (“IO ICs”) that allow ICs within the MCP to communicate with ICs outside of the MCP. If these ICs are small, for instance with a footprint of <5 mm×5 mm, they are sometimes called “chiplets.”

An MCP may comprise an additional interposer layer 117. The SoCs and IO ICs may be mounted to the interposer layer. The interposer typically comprises a silicon substrate with one or more layers of electrical traces, with vias connecting between layers of traces. The interposer also comprises through-silicon vias (TSVs) providing connectivity between the two surfaces of the interposer substrate. The interposer is electrically connected to the package substrate by solder bumps, for instance controlled collapse chip connection (C4) bumps.

ICs within an MCP may connect to each other via die-to-die (D2D) interfaces. D2D interfaces may be routed through the interposer layer. High-performance D2D interfaces typically have a reach of <25 mm, often<10 mm, with power dissipation of <1 pJ/bit. The demands of HPC and AI/ML systems are driving D2D interfaces to data densities of >1 Tbps/mm. Some examples of D2D interfaces are UCIe, HBM4, bunch-of-wires (BoW), XSR, USR, LIPINCON, and Infinity Fabric.

The interposer is on a package substrate 119. The package substrate may comprise one or more layers of electrical traces, with vias connecting between layers and to the two outside surfaces. The package substrate may be on, for example, a printed circuit board 123.

Some IO ICs may be part of an optical IO subsystem that comprises a base IC to which one or more optoelectronic (OE) subassemblies are electrically bonded in a “3D” stack. An OE subassembly (SA) 115 comprises at least electrical-to-optical (E2O) conversion and optical-to-electrical (O2E) conversion functionality. In some embodiments, the base ICs comprise processing, switching, and/or memory functionality.

Some embodiments of an OE SA comprise one or more optical emitters mounted to a passive substrate or an IC. In some embodiments, the emitters comprise one or more microLEDs. Some embodiments of an OE SA comprise one or more photodetectors (PDs) on a passive substrate or on or in an IC. In some embodiments, the emitters and/or PDs are located on a regular grid, for instance a hexagonal close-packed (HCP), square, or rectangular grid. In some embodiments, the center-to-center spacing of grid elements may be in the range of 10 um-100 um.

In some embodiments comprising microLED emitters, a microLED is made from a p-n junction of a direct-bandgap semiconductor material. In some embodiments a microLED is distinguished from a semiconductor laser (SL) as follows: (1) a microLED does not have an optical resonator structure; (2) the optical output from a microLED is almost completely spontaneous emission, whereas the output from a SL is dominantly stimulated emission; (3) the optical output from a 15 microLED is temporally and spatially incoherent, whereas the output from a SL has significant temporal and spatial coherence; (4) a microLED is designed to be driven down to a zero minimum current, whereas a SL is designed to be driven down to a minimum threshold current, which is typically at least 1 mA. In some embodiments a microLED is distinguished from a standard LED by (1) having an emitting region of less than 10 um×10 um; (2) frequently having cathode and anode contacts on top and bottom surfaces, whereas a standard LED typically has both positive and negative contacts on a single surface; (3) typically being used in large arrays for display and interconnect applications. In some embodiments, each microLED is made from the GaN material system with InGaN quantum wells. In some embodiments, each microLED is made from the GaAs or InP material system.

In the example of FIGS. 1a,b, System-on-chip (SOC) ICs 121 are mounted on the interposer 117, with optical IO subassemblies 115 also mounted on the interposer. The ICs and the optical IO sub-assemblies may be in molding compound 111. Multi-channel optical transmission media 113, for example in the form of or including multicore fiber bundles, are coupled to the optical IO subassemblies so as to receive light from the optical emitters and/or pass light to the optical detectors.

In some embodiments, the OE SA is coupled into multi-channel optical transmission media. In some embodiments, the optical transmission media comprise of one or more fiber bundles. A fiber bundle comprises multiple fiber elements, where each fiber element comprises a core surrounded by a concentric cladding. In some embodiments, each fiber is a single-mode fiber. In some embodiments each fiber is a multimode fiber. Multimode fibers may be preferred for use with microLED and LED sources as multimode fibers allow for greater coupling of light from microLEDs than for single-mode fiber. In some further embodiments, the space between the fiber elements may contain some filler material, while in other embodiments the space between fiber elements is empty. In some embodiments, the fiber elements are attached to each other only at the ends of the fiber and are unattached “loose” fiber elements between the ends. In some embodiments, the diameter of the cores is in the range of 25 μm to 50 μm. In some embodiments of a fiber bundle, the cores are located on a regular geometric grid. In some embodiments, this grid is square. In some embodiments, the cores are in a hexagonal close-packed (HCP) configuration such that they lie on an equilateral triangular grid. In some embodiments, the cores of a bundle are not on a regular grid.

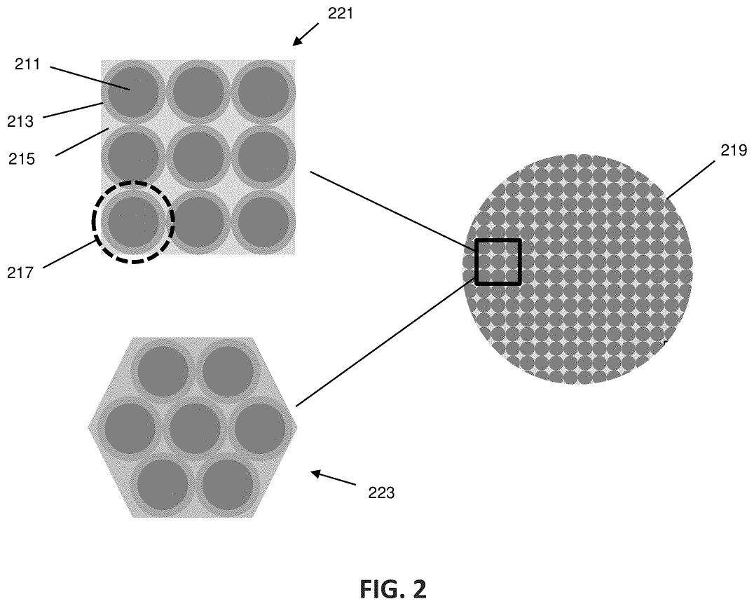

A cross-section of an embodiment of a fiber-optic bundle 219 is shown in FIG. 2. The coherent fiber bundle includes a plurality of cores 211 for the transmission of light. Each core is surrounded by a concentric cladding layer 213 that has a lower index of refraction than the core. Each core and corresponding concentric cladding layer together may be considered a fiber element 217. The space around the fiber elements may be filled with a filler material 215. In some embodiments, the fibers may be arranged in a regular pattern, such as on a square grid 221 or hexagonal grid 223. In some embodiments of a fiber-optic bundle, the positions of each fiber element relative to the other fiber elements are the same at each end of the fiber bundle such that relative positions of the fiber elements are preserved at each end. A fiber-optic bundle in which the relative positions of the fiber elements are preserved is referred to as a “coherent” fiber-optic bundle.

The inventions described herein relate to implementing optical interconnects between integrated circuits (ICs). Each end of the interconnect comprises a base IC to which one or more optoelectronic (OE) subassemblies are electrically bonded in a “3D” stack. An OE subassembly (SA) comprises at least electrical-to-optical (E2O) conversion and/or optical-to-electrical (O2E) conversion functionality. In some embodiments, the base ICs comprise processing, switching, and/or memory functionality.

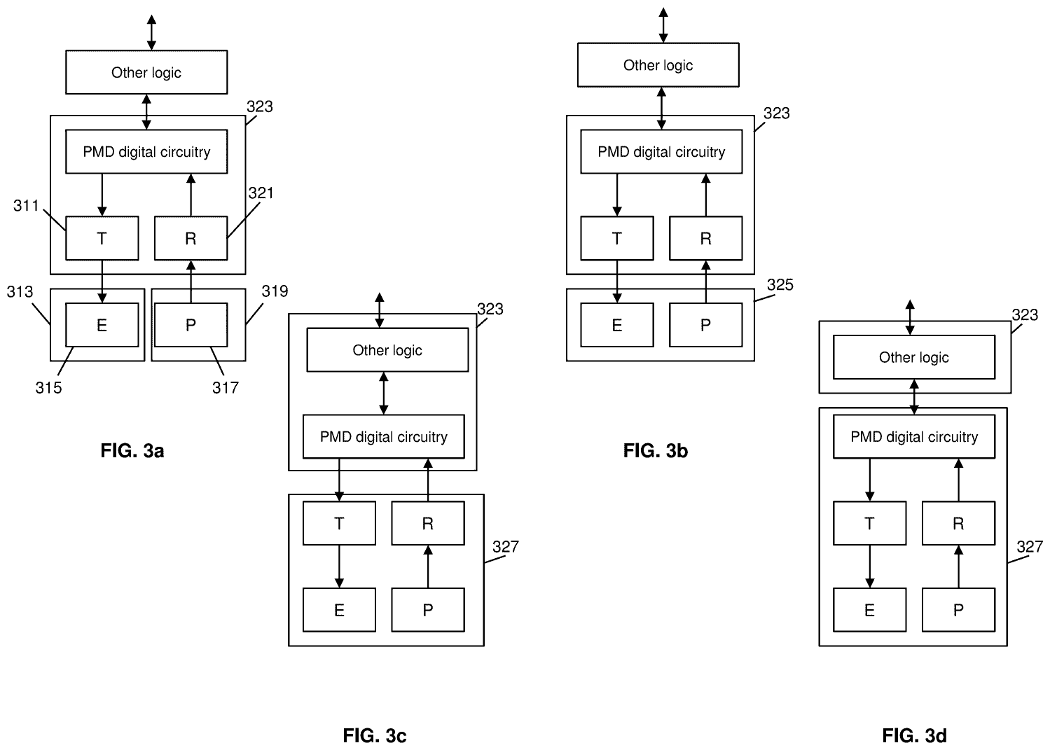

FIGS. 3a-d show block diagrams of various embodiments of one end of an optical interconnect between ICs. The one end of the optical interconnect generally comprises a base IC and one or more passive substrates or ICs, together comprising OE components, transmitter (Tx) and receiver (Rx) circuitry, and other logic.

In some embodiments, the Tx circuitry 311 comprises emitter drivers, each of which takes a logic level input and outputs an analog signal appropriate for driving the emitter, e.g. a current drive with a DC bias term and a modulation term that varies in response to the digital input. In some embodiments, this drive signal may support emphasis of some frequency components relative to others in the driver output, e.g., emphasis of the high-frequency components relative to the low-frequency components. In some embodiments, these transmitter circuits comprise additional digital functionality allowing, for instance, control of the voltage, current, and frequency emphasis levels of the signals driving the emitters, and monitoring of the drive signals and/or the light output of each emitter. In some embodiments, the Tx circuits may include other physical media-dependent (PMD) circuitry such as encoders and/or scramblers.

In some embodiments, the Rx circuitry 321 comprises transimpedance amplifiers (TIAs), each of which takes a photocurrent and amplifies it to a voltage swing, where the gain of the TIA is characterized by a transimpedance gain. In some embodiments, the Rx circuits comprise additional limiting amplifier (LA) stages that amplify the signal to a logic level output. In some embodiments, Rx electronics may support emphasis of some frequency components relative to others, e.g. emphasis of the high-frequency components relative to the low-frequency components. Examples of such a structure includes a decision feedback equalizer (DFE) and a continuous time linear equalizer (CTLE). In some embodiments, these Rx circuits comprise additional digital functionality allowing, for instance, control of the TIA gain, frequency characteristics of the equalizers, and monitoring of the received optical power levels. In some embodiments, the Rx circuits may include other physical media-dependent (PMD) circuitry such as clock recovery circuits, decoders and/or descramblers.

The system may be partitioned such that the functionality is distributed between the different ICs and subassemblies in different ways. In some embodiments, for example as illustrated in FIG. 3a, Tx circuitry and Rx circuitry are part of a base chip 323, separate from OE subassemblies. The Tx circuitry receives signals for transmission from PMD circuitry, also on the base chip, and the Rx circuitry provides received signals to the PMD circuitry. The PMD circuitry may be in communication with other logic circuitry, located off the base chip.

An emitter SA receives signals for driving optical emitters from the Tx circuitry. The emitter SA comprises a separate IC or passive substrate 313 and one or more optical emitters 315. A PD SA provides received signals to the Rx circuitry. The PD SA also comprises a separate IC or passive substrate 319 and one or more PDs 317 or avalanche photodiodes (APDs).

In some embodiments of an OE SA, both the optical emitters and PDs are located on a common OE passive substrate or IC, for example as shown in FIG. 3b. In FIG. 3b, as with the embodiment of FIG. 3a, the Tx and Rx circuitry are located on the base IC, separate from the OE SA.

In some embodiments of an OE SA, for example as shown in FIG. 3c, some part, or all, of the Tx circuitry, for instance the emitter drive circuits, are located on an OE IC 327, while some other Tx circuitry may be located on the base IC. In some embodiments, some part, or all, of the Rx circuitry, for instance the TIAs and LAs, are located on the OE IC, while some other Rx circuitry is located on the base IC. In FIG. 3c, the PMD circuitry is shown as being in the base chip 323, as is the other logic. In some embodiments, however, the OE IC may also include more Tx and Rx circuitry, for instance the PMD circuitry enumerated previously, for example as shown in FIG. 3d. In such embodiments the other logic circuitry may be part of the base chip 323.

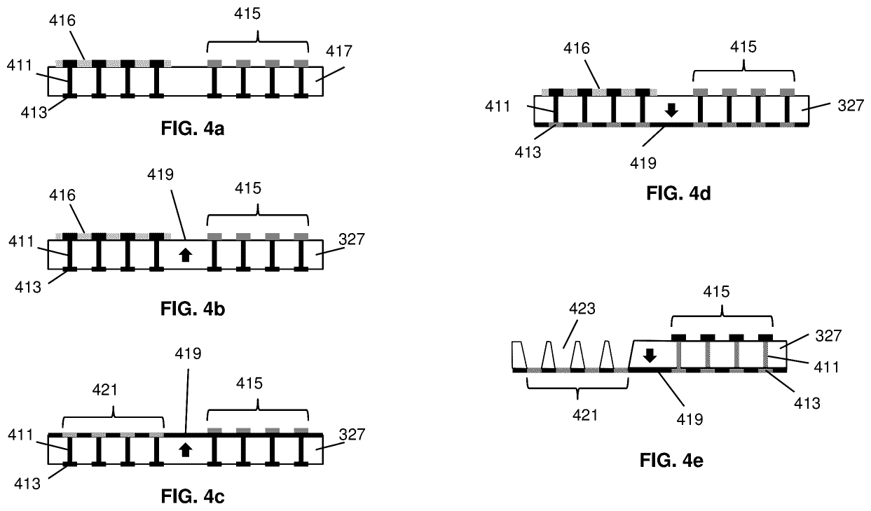

The OE SA may be implemented in numerous ways, some of which are enumerated in FIGS. 4a-e. In some embodiments, for example as shown in FIG. 4a, the OE SA comprises a passive substrate 417 that does not contain active electrical circuits. Such a substrate may be made from silicon, multi-layer ceramic, multi-layer organic, or other materials. In some embodiments, an array of emitters 415 (for instance, microLEDs) and/or PDs 416 may be attached to one surface of the substrate. Such a substrate typically comprises through-substrate vias 411 or through-silicon vias (TSVs) to provide electrical connectivity between the one surface of the substrate and an opposing surface, which includes electrical pads 413.

In some embodiments, for example as shown in FIGS. 4b-e, the OE SA comprises an IC 327, with TSVs 411 connecting between the two surfaces (or “sides”) of the substrate. In the figures, the arrow in the IC points toward the “active” IC side containing the active circuitry 419. The active circuitry may occupy any subset of the IC area. In some embodiments, for example as shown in FIG. 4b, an array of PDs 416 (or APDs) and an array of emitters 415 is bonded to the active side of the IC. In some embodiments, for example as shown in FIG. 4c, an array of PDs/APDs 421 is monolithically integrated with the IC electronics. For the embodiments shown in FIGS. 4a-c, bonding pads 413 on the non-active side of the substrate enable the OE IC to be bonded to a base IC.

In some embodiments, for example as shown in FIG. 4d, an array of emitters 415 and an array of PDs/APDs 416 is bonded to the non-active side of an IC, and is connected to the active surface of the IC by TSVs. In some embodiments, for example as shown in FIG. 4e, an array of emitters 415 is bonded to the non-active side of a OE IC while apertures 423 are etched through the IC on the PD part of the IC to allow “backside” illumination of PDs 421 integrated into the active circuitry side of the IC.

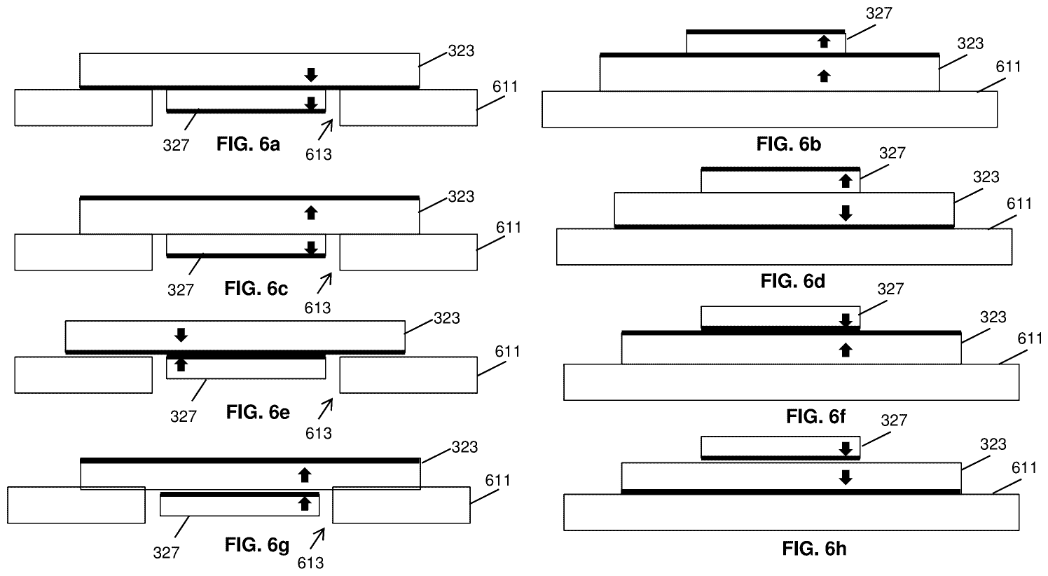

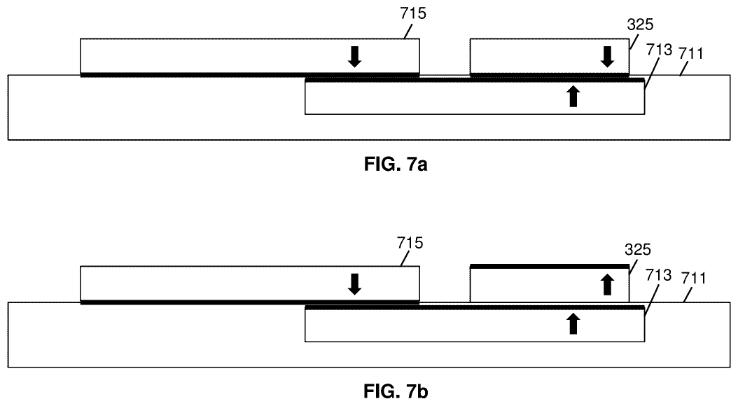

The various OE SA embodiments of FIGS. 4a-e can be bonded to a base IC in a variety of ways to create a “3D” stack, some embodiments of which are shown in FIGS. 6a-h and FIGS. 7a-b. In those figures, arrows in the ICs point toward the “active” side of that IC that contains active circuitry such as transistors. The bonds between the base IC and OE IC may comprise C4 solder bumps, microbumps, or direct bond interconnects (DBI).

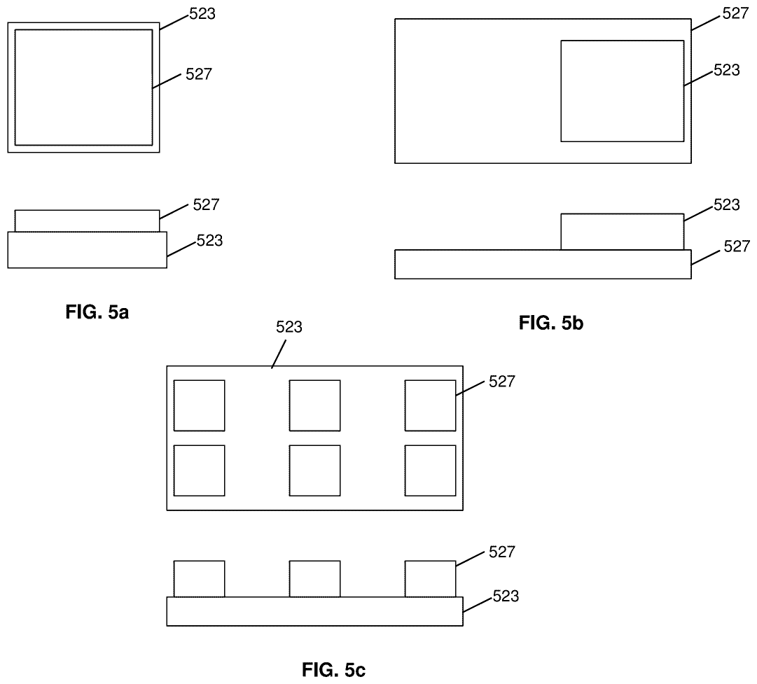

FIGS. 5a-c show top and side views illustrating relative areas of embodiments of base ICs (or passive substrates) and optoelectronic ICs bonded together. In some embodiments, the OE IC or passive substrate 527 has approximately the same footprint as the base IC 523, for example as shown in FIG. 5a. In some embodiments, the OE IC or passive substrate 527 has a larger footprint than the base IC 523, for example as shown in FIG. 5b. In some embodiments, the OE IC has a smaller footprint than the base IC. In some embodiments, each OE IC has a significantly smaller footprint than the base IC 523, and multiple OE ICs 527 are bonded to the base IC, for example as shown in FIG. 5c.

In some embodiments, one or more OE ICs have emitters and/or PDs bonded to their active side, for example as discussed with respect to FIGS. 5a-c. In some such embodiments, those ICs have their non-active side bonded to an active side of a base IC. For example, FIG. 6a shows a base IC 323 having an active side attached to a substrate 611. The substrate may be a package substrate or an interposer, for example. The substrate includes an aperture 613. An OE IC 327 is within the aperture with a non-active side of the OE IC bonded to the active side of the base IC. The active side of the OE IC faces away from the base IC, with a result that light can travel in or through the aperture towards and away from the active side of the OE IC, allowing an optical coupling to any emitters and/or PDs on that active side. For convenience of viewing, arrows are placed within the base IC and OE IC for all of FIGS. 6a-h, with the arrows pointing towards the active side of the ICs in which the arrows are located. In some alternative embodiments, for example as shown in FIG. 6b, the non-active side of the base IC 323 may be bonded to a package substrate or interposer 611, with TSVs to connect the non-active side to the active side. The OE IC 327 is bonded, on its non-active side, to the active side of the base IC.

In some embodiments, the non-active side of one or more OE ICs may be bonded to the non-active side of a base IC. In some such embodiments the OE ICs and the base IC includes TSVs to connect between their two surfaces. Each OE IC comprises emitters and PDs on its active side. In some such embodiments, for example as shown in FIG. 6c, the non-active side of the base IC 323 may be bonded to a package substrate or interposer 611. The package substrate or interposer has one or more apertures 613 to allow optical coupling to the emitters and PDs on the OE IC 327. The base IC is bonded to the package substrate or interposer about the aperture, and the OE IC is largely within the aperture and has its non-active side bonded to the base IC. In some alternative embodiments, the active side of the base IC 323 may be bonded to a package substrate or interposer 611, for example as shown in FIG. 6d, with TSVs coupling the active side and the non-active side of the base IC. The OE IC 323 may have its non-active side bonded to the non-active side of the base IC, with an active side of the OE IC facing away from the base IC. Again, TSVs may electrically couple the non-active and active sides of the OE IC.

In some embodiments, the active side of one or more OE ICs is bonded to the active side of a base IC. In such embodiments, the emitters and/or PDs may be bonded to the non-active side of each OE IC. In some such embodiments, for example as shown in FIG. 6e, the active side of the base IC 323 may be bonded to a package substrate or interposer 611. The package substrate or interposer may have one or more apertures 613 to allow optical coupling to the emitters and PDs on each OE IC, and the base IC may be bonded to the package substrate or interposer over the apertures. The OE IC 327 may be largely within the aperture, with an active side of the OE IC bonded to the active side of the base IC. In some alternative embodiments, for example as shown in FIG. 6f, the non-active side of the base IC 323 may be bonded to a package substrate or interposer 611. The base IC may include TSVs to connect the non-active side to the active side. The active side of the OE IC 327 may be bonded to the active side of the base IC.

In some embodiments, the active side of one or more OE ICs is bonded to the non-active side of a base IC. Emitters and/or PDs may be bonded to the non-active side of the OE ICs. The base IC may include TSVs to connect between non-active and active sides of the base IC. In some such embodiments, the non-active active side of the base IC 323 may be bonded to a package substrate or interposer 611 about one or more apertures 313 of the package substrate or interposer, for example as shown in FIG. 6g. The apertures of the package substrate or interposer allow optical coupling to the emitters and/or PDs on the OE IC, which is largely within the aperture. The OE IC has its active side bonded to the non-active side of the base IC. In some alternative embodiments, the active side of the base IC 323 may be bonded to a package substrate or interposer, with the active side of the OE IC bonded to the non-active side of the base IC.

FIGS. 7a-b are front-side cross-sectional views showing relative arrangements of base ICs, optoelectronic substrates, and molded wafers. FIG. 7a shows a first IC (IC1) 713 embedded in a molded wafer 711. An active side of IC1, about the level of a side of the molded wafer, is bonded to an active side of one or more OE ICs 325. As with other figures, arrows are placed within the ICs for convenience of viewing, with the arrows pointing towards the active side of the ICs in which the arrows are located. Optical emitters and/or PDs are bonded to the non-active side of the OE IC, for example as discussed with respect to FIG. 4a, d, or e. In some embodiments, the wafer may be molded from a polymer.

In some alternative embodiments, the non-active side of an OE IC 325 is bonded to the active side of a first IC (IC1) 713 embedded in a molded wafer 711, for example as shown in FIG. 7b. Optical emitters and/or PDs may be on the active side of the OE IC, for example as discussed with respect to FIG. 4b or c.

A second IC (IC2) 715 may also be bonded to IC1, as shown in both FIGS. 7a and 7b. As illustrated, an active side of IC2 is bonded to a portion of the active side of IC1.

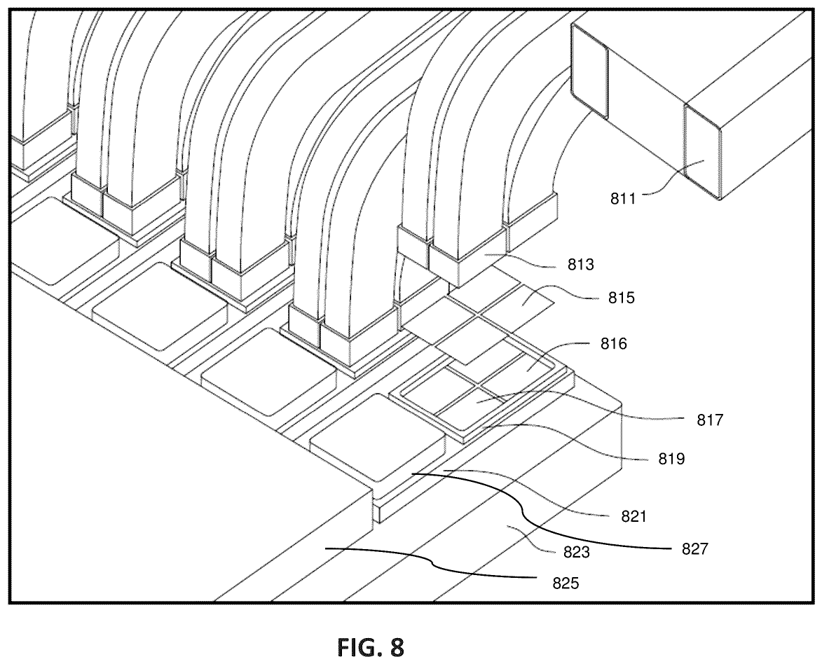

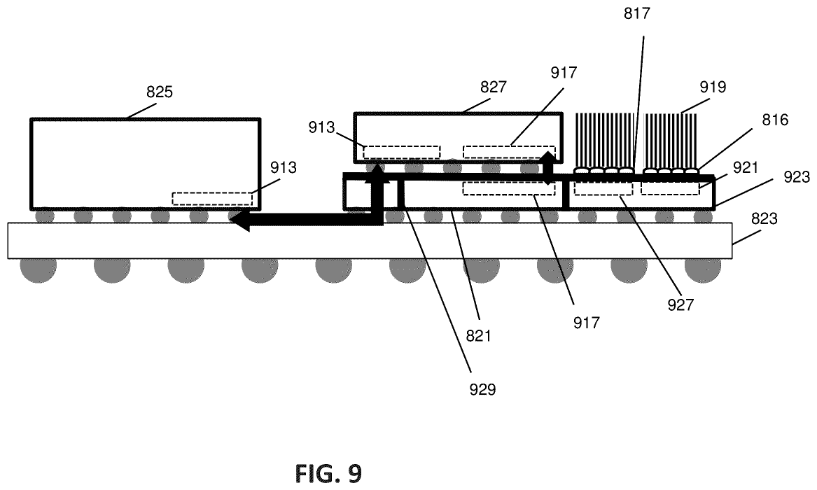

FIGS. 8 and 9 show an example implementation in accordance with aspects of the inventions, with FIG. 8 showing an idealized perspective view and FIG. 9 showing a semi-block diagram cross-section. A GPU 825 is mounted to a silicon interposer 823. The interposer may be in a multi-chip module package, for example. A chiplet 821 is also mounted to the silicon interposer. The GPU and the chiplet are in electronic communication with each other through electrical signal pathways of the interposer.

The chiplet includes electrical signal pathways, for example including TSVs 929, from a surface mounted to the interposer to an area of an opposing surface of the chiplet. A die-to-die (D2D) interface chip 827 is mounted to the area of the opposing surface. The TSVs allow for communication between the D2D interface chip and the GPU. The D2D interface and the GPU may each have D2D interface circuitry 913, for example interface circuitry compliant with a Universal Chiplet Interconnect Express (UCIe) specification.

The chiplet also includes LED driver circuitry 927 and receive circuitry 921, for example including transimpedance amplifiers (TIAs). The LED driver circuitry may be uLED driver circuitry. The chiplet also includes electrical signal pathways between the area of the opposing surface and the LED driver circuitry and receive circuitry. In some embodiments the electrical signal pathways may include buffers in an active layer of the chiplet. The LED driver circuitry and receive circuitry may also be in the active layer of the chiplet.

The driver circuitry is configured to drive LEDs 817. The LEDs are shown as bonded to the opposing surface of the chiplet. Photodetectors 816 are also bonded to the opposing surface of the chiplet. In some embodiments the photodetectors may be in a layer bonded to the chiplet, with the LEDs bonded to that layer. The photodetectors are coupled to the receive circuitry.

The LEDs 817 and photodetectors 816 are each shown as being arranged in arrays, within a frame 819. A fiber bundle 811 including a plurality of multicore fibers is mounted to each of the arrays. Each fiber bundle is comprised of a plurality of fibers. In some embodiments there is a one-to-one correspondence between LEDs and fibers of a bundle. In some embodiments there is also a one-to-one correspondence between photodetectors and fibers of a bundle. The fiber bundles are also shown with a ferrule 813 about their end, for mounting to the frame. In some embodiments, for example as shown in FIG. 9, a fiber plate 919 is on top of the LEDs and photodetectors. In such embodiments, the ferrule may be used to mounting to the fiber plate or the frame. In between ends of the fibers and the LED and photodetectors are lens arrays 815. The lenses of the lens arrays focuses light from the LEDs into the fibers, and focuses light from the fibers onto the photodetectors.

Although the invention has been discussed with respect to various embodiments, it should be recognized that the invention comprises the novel and non-obvious claims supported by this disclosure.

What is claimed is:

1. A device for an optical interconnect, comprising:
a substrate; and
an optoelectronic IC having a first surface mounted to the substrate, with optoelectronic devices on a second surface of the substrate, the optoelectronic devices including microLEDs, the optoelectronic IC including die-to-die (D2D) interface circuitry for receiving information and LED driver circuitry for driving the microLEDs based on the information.

2. The device of claim 1, further comprising a D2D interface chip, the D2D interface chip including D2D interface circuitry coupled to the D2D interface circuitry of the optoelectronic IC.

3. The device of claim 2, wherein the D2D interface chip is mounted to the second surface of the optoelectronic IC.

4. The device of claim 3, wherein a D2D interface between the optoelectronic IC and the D2D interface is a vertical D2D interface.

5. The device of claim 1, further comprising a processor mounted to the substrate, the processor coupled to the optoelectronic IC so as to provide the information to the optoelectronic IC for driving the microLEDs.

6. The device of claim 2, wherein the D2D interface chip includes additional D2D interface circuitry, and further comprising a processor mounted to the substrate, the processor including D2D interface circuitry coupled to the additional D2D interface circuitry of the D2D interface chip.

7. The device of claim 3, wherein the optoelectronic IC includes TSVs providing at least part of an electrical pathway between the substrate and the second surface of the optoelectronic IC.

8. The device of claim 7, further comprising a processor mounted to the substrate, the processor including D2D interface circuitry coupled to the additional D2D interface circuitry of the D2D interface chip by electrical pathways in or on the substrate and the TSVs.

9. The device of claim 8, wherein the D2D interface circuitry of the processor is coupled to the additional D2D interface of the D2D interface chip by a horizontal D2D interface.

10. The device of claim 1, wherein the optoelectronic devices further include photodetectors and receive circuitry coupled to the photodetectors.

11. The device of claim 10, wherein the receive circuitry is coupled to the D2D interface circuitry of the optoelectronic IC.

12. The device of claim 11, further comprising a D2D interface chip, the D2D interface chip including D2D interface circuitry coupled to the D2D interface circuitry of the optoelectronic IC.

13. The device of claim 12, wherein the D2D interface chip is mounted to the second surface of the optoelectronic IC.

14. The device of claim 12, wherein the D2D interface chip includes additional D2D interface circuitry, and further comprising a processor mounted to the substrate, the processor including D2D interface circuitry coupled to the additional D2D interface circuitry of the D2D interface chip.

15. The device of claim 13, wherein the optoelectronic IC includes TSVs providing at least part of an electrical pathway between the substrate and the second surface of the optoelectronic IC, and further comprising a processor mounted to the substrate, the processor including D2D interface circuitry coupled to the additional D2D interface circuitry of the D2D interface chip by electrical pathways in or on the substrate and the TSVs.
